(19) United States
(12) Patent Application Publication
(10) Pub. No.: US 2026/0371585 A1
(43) Pub. Date: Nov. 19, 2026

(54) HIGH VOLTAGE ISOLATION DEVICES AND RELATED MICROELECTRONIC DEVICES AND SYSTEMS

(71) Applicant: Micron Technology, Inc., Boise, ID (US)

(72) Inventor: Michael A. Smith, Boise, ID (US)

(21) Appl. No.: 19/659,289

(22) Filed: Apr. 27, 2026

Related U.S. Application Data
(60) Provisional application No. 63/806,848, filed on May 16, 2025.

(51) Int. Cl. H10B 41/41; H10B 41/35

(52) U.S. Cl. CPC H10B 41/41; H10B 41/35

(57) ABSTRACT

A microelectronic device includes a high voltage isolation (HVIso) block defining a first edge and a second edge opposite the first edge. The HVIso block may include a number of first HVIso devices in a series where each HVIso device of the number of first HVIso devices may include a conductive material extending across a length of the HVIso block. The HVIso block may also include a number of second HVIso devices located closer to the first edge or the second edge than the number of first HVIso devices. The number of second HVIso devices having one or more characteristics than the number of first HVIso devices. The HVIso block may also include an insulative material located between HVIso devices of the number of first HVIso devices and between HVIso devices of the number of second HVIso devices.

### CROSS-REFERENCE TO RELATED APPLICATIONS

This application claims the benefit under 35 U.S.C. § 119(e) of U.S. Provisional Patent Application Ser. No. 63/806,848, filed May 16, 2025, the disclosure of which is hereby incorporated herein in its entirety by this reference.

### TECHNICAL FIELD

The disclosure, in various embodiments, relates generally to microelectronic devices. More specifically, the disclosure relates to high voltage isolation circuits, design and fabrication thereof, and to related devices and systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

### BRIEF DESCRIPTION OF THE SEVERAL VIEWS OF THE DRAWINGS

FIG. 1 shows a simplified schematic view of a high voltage isolation (HVIso) block, in accordance with embodiments of the disclosure.

FIG. 2 is a simplified partial schematic diagram of an example HVIso block showing example variations in active area widths and insulation material widths for HVIso devices including dummy devices, in accordance with embodiments of the disclosure.

FIG. 3 is a plot illustrating a breakdown voltage of an HVIso device over a dopant dosage level in a region of the HVIso device, according to embodiments of the disclosure.

FIG. 4 is a simplified schematic diagram of a series of HVIso devices, according to one or more embodiments of the present disclosure.

FIG. 5 is a simplified block diagram of a memory device including an HVIso block, according to some embodiments of the present disclosure.

FIG. 6 is a simplified, schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” and “horizontal,” are in reference to a major plane of a structure and are not necessarily defined by earth's gravitational field. A “horizontal” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be located (e.g., disposed, formed, positioned, arranged, without limitation) between the “neighboring” features. Put another way, the “neighboring” features may be located directly adjacent one another, such that no other feature intervenes between the “neighboring” features; or the “neighboring” features may be located indirectly adjacent one another, such that at least one feature having an identity other than that associated with at least one the “neighboring” features is located between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “underlying” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization, or other known methods.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in one or more decks (e.g., stack structures) including tiers of conductive structures and dielectric materials. Each vertical memory string may include at least one select device coupled in series to a serial combination of vertically stacked memory cells. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Control logic devices within a base control logic structure underlying a memory array of a memory device (e.g., a non-volatile memory device) have been used to control operations (e.g., access operations, read operations, write operations) on the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the memory device.

Memory devices may incorporate high voltage isolation devices to electrically separate high-voltage domains from low-voltage control circuitry. This may allow signals and power to pass between these domains without a direct conductive connection to protect sensitive components and maintain signal integrity in systems that may incorporate both high and low voltage levels to operate. For example, an erase operation of a memory device typically requires a voltage higher than other operations of the memory device. The high voltage isolation devices may ensure that the voltage required for an erase operation is routed where it is needed without exposing low-voltage control circuits to levels of voltage that may damage or destroy the low-voltage control circuits.

Some microelectronic devices, such as memory devices, apply voltages to various components of the microelectronic device to perform operations. For example, in a memory device, erase operations may include providing a voltage (e.g., about 15-25V) to a number of memory cells. However, during this operation, other components such as page buffer circuits, sense amplifiers, etc., may be damaged by these high voltages. To protect these vulnerable components from harmful voltage levels, a high voltage isolation device (e.g., a high voltage isolation block) may be used. A high voltage isolation (HVIso) block may include a number of HVIso devices that use gates to connect or disconnect certain circuitry from global bitlines or source lines (e.g., of a memory device) to prevent a voltage high enough to damage certain areas (e.g., of the memory device) from being applied to those areas. A number of HVIso devices (e.g., of a high voltage isolation block) may be (e.g., arranged, located, without limitation) in a series where a ratio of an active material of one or more of the HVIso devices compared to a surrounding insulative material may cause at least some of the HVIso devices of the HVIso block to exhibit certain electrical characteristics, such as a maximum voltage an HVIso device can safely withstand before it undergoes electrical breakdown (i.e., a breakdown voltage).

To prevent breakdown, in some memory devices, an applied voltage may be clamped based on the lowest breakdown voltage for a component of the memory device. However, in some cases, some HVIso devices of an HVIso block may exhibit a breakdown voltage that is lower than a voltage required to perform an erase operation. For example, HVIso devices near the edge of the HVIso block may exhibit ratios of active area to insulative material surrounding the active area that cause the edge HVIso devices to exhibit a breakdown voltage lower than those of HVIso devices more proximate to the interior of the HVIso block. However, designing and generating devices with differing ratios of active area and insulative material or different dopant levels may prove to be technically or financially infeasible or prohibitive due to intensive time or cost requirements to design and manufacture. Furthermore, variations in active devices may behave unpredictably and may cause higher failure rates for memory devices.

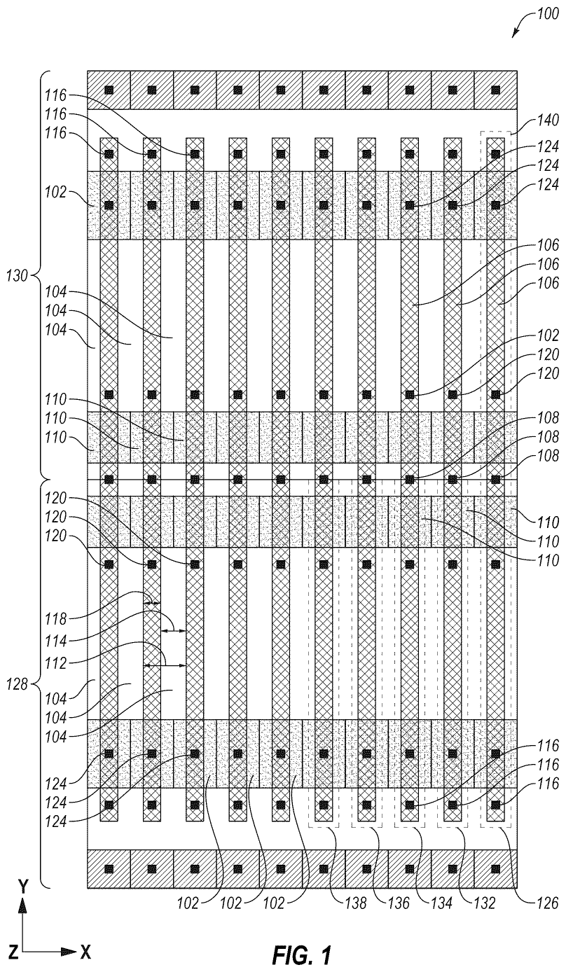

FIG. 1 shows a simplified schematic view of a high voltage isolation (HVIso) block 100 in accordance with embodiments of the disclosure. For example, HVIso block 100 may be part of a microelectronic device, such as a memory device. With the description provided below, it will be readily apparent to one of ordinary skill in the art that microelectronic devices described herein may be included in various relatively larger devices and various electronic systems.

The HVIso block 100 includes a number of HVIso devices (e.g., HVIso devices 126, 132, 134, 136, and 138) located (e.g., arranged) in an array (e.g., a first array of HVIso devices 128 and a second array of HVIso devices 130 of the HVIso block 100 where each HVIso device in each array may be (e.g., arranged, located, without limitation) in a series). For the purposes of discussion, reference to two or more HVIso devices herein refer to two or more HVIso devices in the first array of HVIso devices 128, though any discussion of HVIso devices of the first array of HVIso devices 128 may also apply to the HVIso devices of the second array of HVIso devices 130. Each HVIso device of the HVIso block 100 may include an active area 106, at least one source node 108, a multiplexor (MUX) gate 110, a page buffer isolation gate 102, at least one low voltage node 116, and at least one drain node 120. Each HVIso device may be in electrical communication with a source (e.g., a source plate) (e.g., of a memory device) via the source nodes 108, where the source nodes 108 may each be commonly connected such that a voltage applied to the source nodes 108 may be applied at least substantially equally to each of the source nodes 108.

The active area 106 extends across the HVIso block 100 (e.g., in the Y-direction in FIG. 1). As shown in FIG. 1, the HVIso block 100 may include two arrays, the first array of HVIso devices 128 and the second array of HVIso devices 130 of HVIso devices located (e.g., disposed, formed, without limitation) such that the first array of HVIso devices 128 is located (e.g., arranged) in positions reflecting that of the second array of HVIso devices 130 about the source nodes 108, to which each HVIso device of each array is commonly connected. Furthermore, the active area 106 may extend across the HVIso block 100 such that a segment of active area 106 may extend continuously over two HVIso devices (e.g., over HVIso device 126 and HVIso device 140 of the HVIso block 100 where HVIso device 126 and HVIso device 140 are each connected to a same source node of the source nodes 108). Accordingly, a single active area 106 may be in connection with at least four gates (e.g., two MUX gates 110 and two page buffer isolation gates 102) and, in some embodiments, at least five nodes (e.g., two low voltage nodes 116, two drain nodes 120, and one source node of the source nodes 108).

The HVIso devices of the HVIso block 100 may be located (e.g., arranged) in a respective array at a pitch 112 (e.g., in the X-direction), where the pitch 112 is defined by a width of the active area 106 (the Waa 118) of an HVIso device in a respective array plus a distance between that HVIso device and a next HVIso device in the array or, in other words, the width of the insulative material 104 between each HVIso device in a given array (the Wsti 114).

Each node 124 of the HVIso block 100 may be an electrical contact that may be in electrical communication with one or more other circuits or structures (e.g., of an associated memory device). For example, the low voltage nodes 116 may be in electrical communication with one or more page buffers of an associated memory device. Furthermore, the drain nodes 120 may be in communication (e.g., via one or more additional conductive pathing structures) with one or more bitlines of the memory device. For example, various conductive routing structures may provide an electrical path from the drain nodes 120 to one or more bitlines that may be connected to a stack structure of the memory device. The stack structure of the memory device may include a vertically alternating (e.g., in a Z-direction orthogonal to the Y-and X-directions) sequence of conductive structures and insulative structures located (e.g., arranged, positioned, formed, without limitation) in tiers. Each of the tiers of the stack structure may include at least one of the conductive structures vertically neighboring at least one of the insulative structures. In some embodiments, the conductive structures are formed of and include tungsten (W) and the insulative structures are formed of and include silicon dioxide (SiO₂). The conductive structures and insulative structures of the tiers of the stack structure may each individually be substantially planar, and may each individually exhibit a desired thickness.

Intersections of cell pillar structures and the conductive structures of the tiers of the stack structure may define vertically extending strings of memory cells coupled in series with one another within the memory device. In some embodiments, the memory cells formed at the intersections of the conductive structures and the cell pillar structures within each the tiers of the stack structure comprise so-called “MONOS” (metal-oxide-nitride-oxide-semiconductor) memory cells. In additional embodiments, the memory cells comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. The floating gates may horizontally intervene between central structures of the cell pillar structures and the conductive structures of the different tiers of the stack structure. Accordingly, each bitline may be connected to an end (e.g., a longitudinal end proximate to the bitline) of a string defined in the stack structure of the memory device such that a voltage applied to a bitline may be provided to the cells of a string of the stack structure to perform operations (e.g., read, write, or erase operations). Each bitline may operate independently from each other to provide a voltage to the strings connected to each bitline.

The HVIso block 100 includes an insulative material 104 (e.g., a dielectric material) located (e.g., disposed, formed, without limitation) between each HVIso device of the HVIso block 100. In some embodiments, a gap (e.g., a shallow trench isolation gap) may be defined between the active area 106 of each of the HVIso devices of a given array or series. The gap may then be filled with the insulative material 104. The distance defined by the gap (i.e., the width of the gap) between each HVIso device is the Wsti 114.

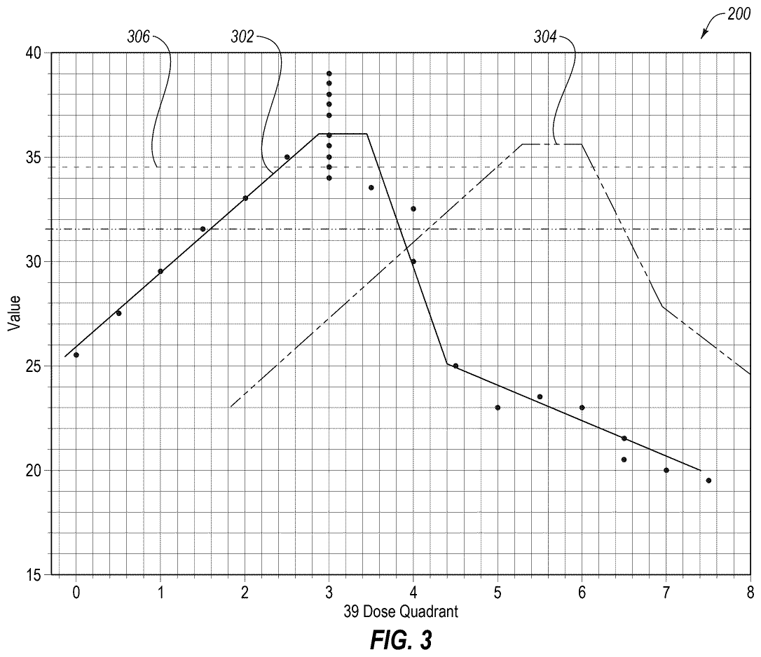

In some embodiments, at least part of the active area 106 on each of the HVIso devices is lightly doped to generate a lightly doped drain or LDD region (e.g., a lightly doped n-region) of the active area. The LDD region allows the electrical field near the drain nodes 120 to be spread to reduce hot carrier injection, which may damage one or more materials of the HVIso block 100 over time (e.g., responsive to read, write, or erase operations). The ratio of the dopant in the LDD region, along with other factors such as the ratio of the active area 106 and the surrounding insulative material 104, may affect the breakdown voltage curve for a given HVIso device, as discussed in more detail below with regard to FIG. 3.

In one example operation wherein the HVIso block 100 is part of a memory device, the HVIso block 100 may operate in a first operating mode (also referred to herein as a “first mode of operation”) and a second operating mode (also referred to herein as a “second mode of operation”). In the first operating mode, a voltage may be applied to the page buffer isolation gates 102 to allow a voltage to be applied to the drain nodes 120 and the low voltage nodes 116. In the first operating mode, the MUX gate 110 for each HVIso device is grounded such that a voltage is not allowed to pass from the source nodes 108 to the drain nodes 120 to isolate the drain nodes 120 (i.e., the bitlines) from the common source nodes 108 while receiving a voltage via the page buffer isolation gate 102. Furthermore, in the first operating mode, the voltage applied to the low voltage nodes 116 via the page buffer isolation gates 102 may interact with the stack structure of the memory device to allow a voltage to be applied to either the source nodes 108 via a source (e.g., a source plate) of the memory device or to the nodes of the page buffer isolation gate 102 to pass to the low voltage nodes 116.

In the second operating mode, a voltage is applied to the source nodes 108 via the source of the memory device and the MUX gates 110 for each HVIso device is turned on such that the source nodes 108 voltage passes to each drain node 120 and to the bitlines in electrical connection with each drain node of the drain nodes 120. Furthermore, in the second mode of operation, the page buffer isolation gate 102 is turned off such that the voltage applied by the source nodes 108 is isolated from the low voltage nodes 116. For example, in the second mode of operation, an erase voltage (e.g., around 20V) may be applied to the HVIso block 100 via the source nodes 108. The voltage applied to the source nodes 108 may then be provided to the bitlines via the drain nodes 120 and then to each pillar of the stack structure of the memory device to bring the voltage of the stack structure to the erase voltage to cause data stored in the stack structure to be the same logic level (e.g., a logic level 1 or a logic level 0). Moreover, because in the second mode of operation the page buffer isolation gate 102 is off for each of the HVIso devices, the voltage applied via the source nodes 108 is isolated from the low voltage nodes 116, thus protecting the low voltage nodes 116 from the relatively high voltage.

In some embodiments, one or more of the HVIso devices of the HVIso block 100 may operate as or otherwise be in the form of a dummy device. For example, HVIso devices operating as dummy devices may be structurally the same or at least substantially similar to the others of the HVIso devices (e.g., active HVIso devices), but may not be connected to other circuitry (e.g., of a memory device) that may include the HVIso block 100 such that operations of a device including the HVIso block 100 (e.g., a memory device) may not substantially affect, or may not be substantially affected by, the dummy devices (e.g., when performing read, write, or erase operations). Stated another way, the active HVIso devices of the HVIso block 100 may be connected to circuitry not connected to the dummy devices. For example, the dummy devices may be connected to the source nodes 108 and the drain nodes 120 such that a voltage may be applied to the dummy devices to bias the dummy devices, but the dummy devices may not be connected to bitlines (e.g., of the memory device) or to page buffer circuitry that may be in connection with the active HVIso devices.

In some embodiments, the dummy devices may exhibit one or more characteristics (e.g., structural characteristics) that are different than others of the HVIso devices located (e.g., arranged) in series with the dummy devices. For example, an active area 106 of the dummy devices may have a Waa 118 (i.e., a width of the active area 106) different than a Waa 118 of the active area 106 of the active HVIso devices. For example, the Waa 118 of the dummy devices of the HVIso devices may have a Waa 118 that is smaller or larger than the Waa 118 of active HVIso devices. Furthermore, a dummy device of a number of dummy devices may have an active area with a Waa 118 different than others of the number of dummy devices.

Furthermore, a Wsti 114 between dummy devices or between a dummy device and an active HVIso device within a series, may be different than a Wsti 114 between active HVIso devices within the series (e.g., in the first array of HVIso devices 128 or the second array of HVIso devices 130). Moreover, in some embodiments, the Wsti 114 between two dummy devices of three or more dummy devices within the series may be the same or different than other Wsti 114 between two dummy devices within the series such that a pitch 112 of each HVIso device 126 of the first array of HVIso devices 128 and the second array of HVIso devices 130 may be consistent or varied over the series of HVIso devices within the first array of HVIso devices 128 and the second array of HVIso devices 130.

In some embodiments, the dummy devices may be (e.g., located, arranged, positioned, without limitation) in series with active HVIso devices. For example, in some embodiments, the dummy devices may be (e.g., located, arranged, positioned, without limitation) in a series with the active HVIso devices such that the dummy devices are closer to an edge of the HVIso block 100 (e.g., an edge parallel to a longitudinal, axis of an active area 106 of the HVIso device 126) than the active HVIso devices. As a specific, non-limiting example, the three right-most HVIso devices of the HVIso block 100 (i.e., HVIso device 126, HVIso device 132, and HVIso device 134) shown in FIG. 1 may be dummy devices where interior devices, such as HVIso device 136, and HVIso device 138, may be active devices. Though discussed and shown having a certain number of HVIso devices in the HVIso block 100, the HVIso block 100 may have any number of HVIso devices such that the first array of HVIso devices 128 and the second array of HVIso devices 130 may each have any number of HVIso devices (e.g., located, arranged, without limitation) in a series (e.g., within respective arrays, such as the first array of HVIso devices 128 and the second array of HVIso devices 130).

Furthermore, in some embodiments, each HVIso device of the HVIso block 100 may be an active HVIso device where one or more edge HVIso devices (e.g., devices closer to an edge of the HVIso block 100 relative to others of the HVIso devices) may have an active area with a Waa 118 different than others of the HVIso devices (e.g., HVIso devices located closer to a longitudinal center of the HVIso block 100 than the edge HVIso devices). Additionally, a spacing (i.e., Wsti 114) between each active HVIso device (e.g., the edge HVIso devices) may be varied over the series of HVIso devices such that the Wsti 114 between two active HVIso devices (e.g., two active edge HVIso devices) may be larger or smaller than the Wsti 114 between others of the HVIso devices of the HVIso block 100.

Thus, a microelectronic device, according to embodiments of the disclosure, includes an HVIso block defining a first edge and a second edge opposite the first edge. The HVIso block may include a number of first HVIso devices located (e.g., arranged) in a series in a first direction. Each of the HVIso devices may include a conductive material extending across a length of the HVIso block in a second direction perpendicular to the first direction. The HVIso block may also include a number of second HVIso devices, each of the number of second HVIso devices located closer to the first edge or the second edge than the number of first HVIso devices, the number of second HVIso devices having one or more characteristics that are different than the number of first HVIso devices. Each HVIso device of the second HVIso devices comprising a conductive material extending across a length of the HVIso block in the second direction. The HVIso block may also include an insulative material located (e.g., disposed, formed, without limitation) between each HVIso device of the number of first HVIso devices and between each HVIso device of the number of second HVIso devices.

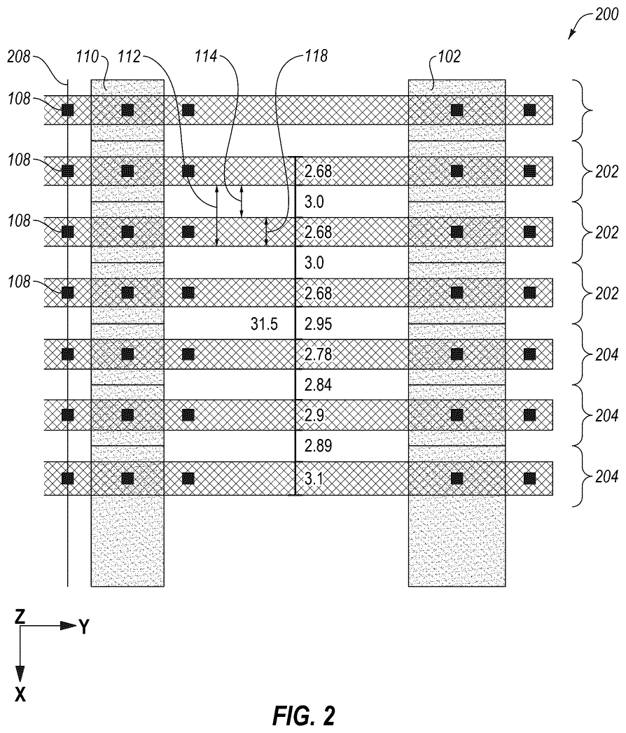

FIG. 2 is a simplified partial schematic diagram 200 of an example HVIso block showing example variations in active area widths and insulation material widths for HVIso devices including dummy devices, in accordance with embodiments of the disclosure. Referring to FIGS. 1 and 2 together, schematic diagram 200 shows an arrangement of active HVIso devices 202 and dummy HVIso devices 204 where the dummy HVIso devices 204 are located (e.g., arranged, positioned, without limitation) proximate to an edge of the HVIso block 100 and have varying Waa 118 and Wsti 114 (e.g., measured in microns) relative to each other and the closest active HVIso device 202 compared to the Waa 118 and Wsti 114 of each active HVIso device 202 relative to each other. Though described where HVIso devices 204 are dummy devices, the dummy HVIso devices 204 may be in the form of active devices having varying dimensions relative to other HVIso devices of the HVIso block 100, such as active HVIso devices 202.

As shown in FIG. 2, the active HVIso devices 202 may have an at least substantially consistent pitch 112 relative to each other where the Waa 118 and/or the Wsti 114 of the dummy HVIso devices 204 may vary relative to each other and to a closest active HVIso device 202. Each dummy HVIso device 204 and active HVIso device 202 may receive a voltage from the source nodes 108. For example, a voltage may be applied to the source nodes 108 via a source wire 208 such that each source node 108 connected to the source wire 208 may receive the at least substantially same voltage. By using dummy HVIso devices 204 at the edge of the HVIso block, the breakdown voltage of the active HVIso devices 202 may be more consistent over all active HVIso devices 202 of the HVIso block to maintain consistent breakdown voltage performance across the entire HVIso block. Furthermore, by varying the Waa 118 and the Wsti 114 of the dummy devices, the breakdown voltage, which may otherwise drop for devices closer to the edge of the HVIso block, may be adjusted to be at least substantially consistent (e.g., within from about 0.01V to about 5V) with the breakdown voltage of the active HVIso devices 202, thereby avoiding the voltage applied to the source nodes 108 from being clamped to a lowest detected breakdown voltage of the active HVIso devices 202 and the dummy HVIso devices 204. This may allow a breakdown voltage for each active device to be above that needed to perform certain operations, such as an erase operation.

FIG. 3 is a plot 300 illustrating a breakdown voltage (the Y-axis of the plot 300) of a given HVIso device as a function of a dopant dosage level (the X-axis of the plot 300) in the LDD region of the given HVIso device (e.g., an HVIso device shown in FIG. 1), according to embodiments of the disclosure. Referring to both FIG. 1 and FIG. 3 together, as shown in the plot 300, there may be a narrow band of dosage where the breakdown voltage peaks at levels that may be useful for one or more operations of the HVIso block 100 such as levels that exceed the erase voltage threshold 306. For example, during an erase operation, the breakdown voltage must reach a certain level for each HVIso device of the HVIso block 100 to successfully perform the erase operation (e.g., the voltage must exceed the erase voltage threshold 306 to successfully perform an erase operation). The proper dosage may be affected by the ratio of the active area 106 and the surrounding insulative material 104 for each HVIso device.

For example, a curve 302 may be indicative of a breakdown voltage curve for an interior HVIso device (e.g., HVIso device 138 or HVIso device 136) within an array (e.g., the first array of HVIso devices 128) of HVIso devices where there is a consistent ratio of active area 106 and surrounding insulative material 104 for each HVIso device. A curve 304 may be indicative of a breakdown voltage of an HVIso device as a function of dopant dosage level where there is a higher ratio of insulative material 104 relative to the active area 106 for the HVIso device compared to an HVIso device exhibiting behavior shown in curve 302 (e.g., a device at the edge of the HVIso block 100 such as HVIso device 134, which may cause similar effects in devices proximate the edge-most device, such as HVIso device 132 or HVIso device 126). Because of the differing ratio of insulative material 104 to the active area 106, the breakdown voltage as a function of dopant dosage level of an HVIso device represented by curve 304 exhibits differing characteristics such that a high dosage of dopant is required to attain a breakdown voltage high enough to allow a successful erase operation (i.e., a breakdown voltage above the erase voltage threshold 306). This may cause issues in situations where a high breakdown voltage is desired (e.g., during an erase operation) where there may be a varying ratio of insulative material 104 and active area 106 over a series of HVIso devices (e.g., the first array of HVIso devices 128 or the second array of HVIso devices 130) as a same dosage level for each HVIso device of the series may not be sufficient for some of the HVIso devices to have a breakdown voltage above the erase voltage threshold 306.

For example, during manufacturing of the HVIso block 100, each HVIso device of the HVIso block 100 may receive the same implant (e.g., dosage amount of dopant) to the LDD region of each HVIso device, such as HVIso device 126, as varying dopant amounts for each individual HVIso device may prove to be technically or financially infeasible or prohibitive due to intensive time or cost requirements. However, HVIso devices towards the edges of a respective array (e.g., the one or more HVIso devices at the beginning or end of an array, such as the first array of HVIso devices 128), may have varying ratios of active area 106 compared to insulative material 104, which, as discussed above, may cause the edge devices to exhibit behavior indicative of a higher insulative material 104 relative to the active area 106 compared to HVIso devices closer to the interior of the array.

As shown in FIG. 3, a voltage applied to reach the peak of curve 302 would lead to a breakdown voltage of the edge HVIso devices to be below the erase voltage threshold 306 at a prescribed dopant dosage, which may cause an erase operation to fail. For example, a dopant dosage amount corresponding to the value 3 of the X-axis of the plot 300 will allow a breakdown voltage of the interior device, to reach above the erase voltage threshold 306, but the breakdown voltage of the edge device at that same dopant dosage value, would cause the edge device to exhibit a breakdown voltage below the erase voltage threshold 306. Accordingly, when a voltage is applied to the HVIso devices, the voltage may be clamped or limited by a lowest detected breakdown voltage of every HVIso device of the HVIso block 100. The breakdown voltage of the edge device (e.g., HVIso device 126) shown in curve 304 would cause the voltage applied to the HVIso devices to be below the erase voltage threshold 306, which may cause an erase operation of the memory device to fail or, if the voltage is not clamped, may cause damage to the HVIso device exhibiting the lower breakdown voltage.

Referring to FIGS. 1-3 together, varying the width of the active area 106 of HVIso devices of the HVIso block 100 and/or varying distance between two or more HVIso devices of the HVIso block 100 may allow each HVIso device of the HVIso block 100 to have a more consistent breakdown voltage across a series of HVIso devices. Furthermore, the varying width of the active area 106 may also allow a voltage (e.g., an erase voltage) applied to each HVIso device to reach a required level to accomplish a function (e.g., an erase function) compared to conventional techniques, which may exhibit operation failures due to edge devices of an HVIso block behaving differently (e.g., edge HVIso devices having a lower breakdown voltage than other HVIso devices of the HVIso block) which may lead to unexpected errors when performing certain operations, such as erase operations. Additionally, by using dummy devices (e.g., non-active devices) having differing width of the active area 106 and/or spacing between devices, a consistent breakdown voltage may be achieved for the interior active devices without having to create new models and spend extra time for design and manufacture for edge devices having different specifications than interior devices. Furthermore, by using dummy devices as edge devices of an HVIso device array, each of the active devices may behave as an interior device, that is, each active device may have a consistent breakdown voltage across the array of active HVIso devices.

Thus, a microelectronic device, according to some embodiments of the disclosure, includes a source structure and an HVIso block defining a first edge and a second edge opposite the first edge. The HVIso block includes a number of HVIso devices (e.g., located, arranged, without limitation) in a series in a first direction. Each HVIso device of the number of HVIso devices may include a source node in electrical contact with the source structure, a drain node, a MUX gate located (e.g., disposed, formed, without limitation) between the source node and the drain node and configured to electrically isolate the source node from the drain node, a low voltage node, an isolation gate located between the drain node and the low voltage node and configured to prevent a flow of electricity from flowing from the source node to the low voltage node, and a conductive material extending across a length of the HVIso block and operably connected to the source node, the drain node, the MUX gate, the isolation gate, and the low voltage node. The HVIso block may also include a number of dummy devices (e.g., located, arranged, without limitation) in the series of the number of HVIso devices and located closer to the first edge or the second edge than the number of HVIso devices. The number of dummy devices may have one or more characteristics that are different than one or more characteristics of the number of HVIso devices. Furthermore, the HVIso block may include an insulative located between each HVIso device of the number of HVIso devices and the number of dummy devices.

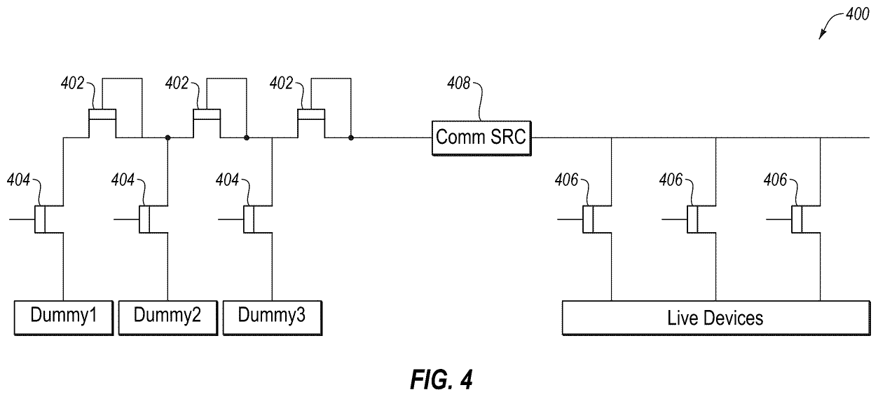

FIG. 4 is a simplified schematic diagram 400 of a series of HVIso devices, according to one or more embodiments of the present disclosure. The schematic diagram 400 shows a series of dummy HVIso devices 404 and a series of active HVIso devices 406 in connection with a common source 408. Furthermore, voltage drop diodes 402 are located between each dummy HVIso device 404 shown in the schematic diagram 400 and between a right-most dummy HVIso device 404 and the common source 408. The voltage drop diodes 402 may cause a voltage applied to the series of dummy HVIso devices 404 via the common source 408 to be stepped down as the voltage moves from the interior (e.g., closer to the common source 408) to the edge of the series of dummy HVIso devices 404. For example, the voltage drop diodes 402 may be configured to step down an applied voltage to the dummy HVIso devices 404 such that the applied voltage is below a breakdown voltage for each dummy HVIso device 404.

In some embodiments, the dummy HVIso device 404 may be at least substantially structurally similar to the active HVIso devices 406 (e.g., an at least substantially same Waa 118 (see FIG. 2) and/or an at least substantially same Wsti 114 (see FIG. 2) between or adjacent to the dummy HVIso devices 404) with one or more of the voltage drop diodes 402 located (e.g., disposed, formed, without limitation) between the dummy HVIso devices 404. Furthermore, in some embodiments, the dummy HVIso devices 404 may have varying characteristics relative to the active HVIso devices 406 (e.g., larger or smaller Waa 118 and/or varying Wsti 114 between or adjacent to the dummy HVIso devices 404).

Though shown with one voltage drop diode 402 between or adjacent to each dummy HVIso device 404, any number of voltage drop diodes 402 may be located (e.g., disposed) between or adjacent to each dummy HVIso device 404. For example, a connected series of voltage drop diodes 402 may be located (e.g., disposed, formed, without limitation) between two of the dummy HVIso devices 404 such that each voltage drop diode 402 is effective to step down an applied voltage as voltage is passed from one dummy HVIso device 404 to a next serially connected dummy HVIso device 404.

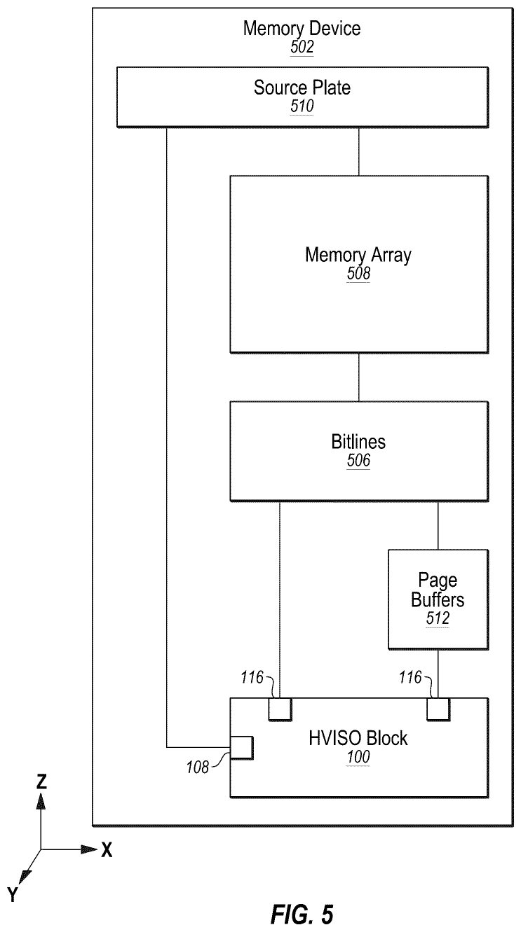

FIG. 5 is a simplified block diagram of a memory device 502 including the HVIso block 100, according to some embodiments of the present disclosure. The memory device 502 may include a source 510 (e.g., a source plate), a memory array 508, bitlines 506, page buffers 512, and the HVIso block 100. The HVIso block 100 may be in electrical connection with the source 510 via the source nodes 108, the bitlines 506 via the drain nodes 120, and the page buffers 512 via the low voltage nodes 116. The bitlines 506 may be in connection with various components of the memory array 508, which may in turn be in electrical communication with the source 510.

The memory array 508 may be in the form of a stack structure that may include a vertically alternating (e.g., in the Z-direction) sequence of conductive structures and insulative structures (e.g., located, arranged, without limitation) in tiers. Each of the tiers of the stack structure may include at least one of the conductive structures vertically neighboring at least one of the insulative structures. In some embodiments, the conductive structures are formed of and include tungsten (W) and the insulative structures are formed of and include silicon dioxide (SiO₂). The conductive structures and insulative structures of the tiers of the stack structure may each individually be substantially planar, and may each individually exhibit a desired thickness.

Intersections of cell pillar structures and the conductive structures of the tiers of the stack structure may define vertically extending strings of memory cells coupled in series with one another within the memory device. In further embodiments, the memory cells comprise so-called “floating gate” memory cells including floating gates (e.g., metallic floating gates) as charge storage structures. The floating gates may horizontally intervene between central structures of the cell pillar structures and the conductive structures of the different tiers of the stack structure.

Voltage may be applied to the source 510, which may then, through various conductive routing structures, be provided to the HVIso block 100 via the source nodes 108. Depending on which operating state the HVIso block 100 is in, the voltage provided to the source nodes 108 may be provided to the bitlines 506. Each bitline of the bitlines 506 may be connected to an end (e.g., a longitudinal end proximate to the bitline) of a string defined in the stack structure of the memory device 502 such that a voltage applied to a bitline may be provided to the cells of a string of the stack structure to perform operations (e.g., read, write, or erase operations). Each bitline may operate independently from each other to provide a voltage to the strings connected to each bitline. Each bitline may also receive an at least substantially same voltage such as, for example, during an erase operation.

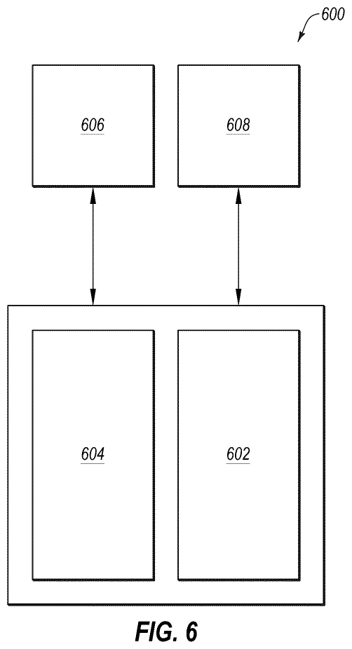

Microelectronic devices (e.g., the HVIso block 100 (FIG. 1)) in accordance with embodiments of the disclosure may be used in embodiments of electronic systems of the disclosure. For example, FIG. 6 is a schematic block diagram of an illustrative electronic system, according to embodiments of disclosure. The electronic system 600 may comprise, for example, a computer or computer hardware component, a server or other networking hardware component, a cellular telephone, a digital camera, a personal digital assistant (PDA), portable media (e.g., music) player, a Wi-Fi® or cellular-enabled tablet such as, for example, an iPAD® or SURFACE® tablet, an electronic book, a navigation device, etc. The electronic system 600 includes at least one memory device 602. The memory device 602 may include, for example, a microelectronic device (e.g., including the HVIso block 100 (FIG. 1)) previously described herein. The electronic system 600 may further include at least one electronic signal processor device 604 (often referred to as a “microprocessor”). The electronic signal processor device 604 may, optionally, comprise a microelectronic device (e.g., including the HVIso block 100 (FIG. 1)) previously described herein.

While the memory device 602 and the electronic signal processor device 604 are depicted as two (2) separate devices in FIG. 6, in additional embodiments, a single (e.g., only one) memory/processor device having the functionalities of the memory device 602 and the electronic signal processor device 604 is included in the electronic system 600. In such embodiments, the memory/processor device may include a microelectronic device (e.g., the HVIso block 100 (FIG. 1)) previously described herein. The electronic system 600 may further include one or more input devices 606 for inputting information into the electronic system 600 by a user, such as, for example, a mouse or other pointing device, a keyboard, a touchpad, a button, or a control panel. The electronic system 600 may further include one or more output devices 608 for outputting information (e.g., visual or audio output) to a user such as, for example, a monitor, a display, a printer, an audio output jack, and/or a speaker. In some embodiments, the input device 606 and the output device 608 comprise a single touchscreen device that can be used both to input information to the electronic system 600 and to output visual information to a user. The input device 606 and the output device 608 may communicate electrically with one or more of the memory device 602 and the electronic signal processor device 604.

Thus, an electronic system, according to embodiments of the disclosure, includes an input device, an output device, a processor device operably coupled to the input device and the output device, and a memory device operably coupled to the processor device. The memory device may include a source structure, an HVIso block defining a first edge, and a second edge opposite the first edge. The HVIso block may include a number of HVIso devices in a series in a first direction. Each HVIso device of the number of HVIso devices include a source node in electrical contact with the source structure, a drain node, a MUX gate configured to electrically disconnect the source node from the drain node, a low voltage node, an isolation gate configured to electrically disconnect the source node from the low voltage node, a conductive material extending across a length of the HVIso block and operably connected to the source node, the drain node, the MUX gate, the isolation gate, and the low voltage node, a number of dummy devices, in the series of the number of HVIso devices and located (e.g., disposed, formed, without limitation) closer to the first edge or the second edge than the number of HVIso devices, the number of dummy devices where a distance between at least two dummy devices in the series is different than a distance between each of the number of HVIso devices. The HVIso block also includes an insulative material located between each HVIso device of the number of first HVIso devices and the number of dummy devices in the series.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device comprising:
a high voltage isolation (HVIso) block defining a first edge and a second edge opposite the first edge, the HVIso block comprising:
a number of first HVIso devices in a series in a first direction, each HVIso device of the number of first HVIso devices comprising a conductive material extending across a length of the HVIso block in a second direction perpendicular to the first direction;
a number of second HVIso devices, each of the number of second HVIso devices located closer to the first edge or the second edge than the number of first HVIso devices, the number of second HVIso devices having one or more characteristics that are different than the number of first HVIso devices, each HVIso device of the number of second HVIso devices comprising a conductive material extending across a length of the HVIso block in the second direction; and
an insulative material located between HVIso devices of the number of first HVIso devices and between HVIso devices of the number of second HVIso devices.

2. The microelectronic device of claim 1, wherein a distance between each HVIso device of the number of first HVIso devices is substantially consistent across the series of first HVIso devices.

3. The microelectronic device of claim 1, wherein the insulative material fills a space located between each of the number of first HVIso devices and each of the number of second HVIso devices.

4. The microelectronic device of claim 1, wherein a width of the conductive material of each of the number of the first HVIso devices is at least substantially consistent across the series of first HVIso devices.

5. The microelectronic device of claim 4, wherein the conductive material of one or more of the number of second HVIso devices has a width that is at least substantially different than a width of each of the number of first HVIso devices.

6. The microelectronic device of claim 1, wherein a distance between two of the number of second HVIso devices is at least substantially different than a distance between each of the number of first HVIso devices.

7. The microelectronic device of claim 1, wherein each HVIso device of the number of first HVIso devices is electrically connected with one or more bitlines of the microelectronic device.

8. The microelectronic device of claim 1, wherein each HVIso device of the number of second HVIso devices is electrically disconnected with one or more bitlines of the microelectronic device.

9. The microelectronic device of claim 1, further comprising a voltage drop diode connected between two HVIso devices of the number of second HVIso devices.

10. The microelectronic device of claim 1, further comprising three or more of the number of second HVIso devices in a series and located proximate to the first edge of the HVIso device and three or more of the number of second HVIso devices in a series and located proximate to the second edge of the HVIso device.

11. The microelectronic device of claim 1, wherein a difference in a breakdown voltage between each of the number of first HVIso devices and each of the number of second HVIso devices is between a range from about 0.01V to about 5V.

12. A microelectronic device comprising:
a source structure;
a high voltage isolation (HVIso) block defining a first edge and a second edge opposite the first edge, the HVIso block comprising:
a number of HVIso devices in a series in a first direction, each HVIso device of the number of HVIso devices comprising:
a source node in electrical contact with the source structure;
a drain node;
a multiplexor (MUX) gate located between the source node and the drain node and configured to electrically isolate the source node from the drain node;
a low voltage node;
an isolation gate located between the drain node and the low voltage node and configured to prevent a flow of electricity from flowing from the source node to the low voltage node;
a conductive material extending across a length of the HVIso block and operably connected to the source node, the drain node, the MUX gate, the isolation gate, and the low voltage node;
a number of dummy devices in the series of the number of HVIso devices and located closer to the first edge or the second edge than the number of HVIso devices, the number of dummy devices having one or more characteristics that are different then the number of HVIso devices; and
an insulative material located between each HVIso device of the number of first HVIso devices and between each dummy device of the number of dummy devices.

13. The microelectronic device of claim 12, wherein each of the number of HVIso devices and the number of dummy devices are in a series where the dummy devices are located within the series closer to the first edge or the second edge of the HVIso block than the HVIso devices.

14. The microelectronic device of claim 12, wherein the one or more low voltage nodes are each electrically connected to one or more page buffers of the microelectronic device.

15. The microelectronic device of claim 12, wherein the conductive material of one or more of the number of dummy devices have a different width than the conductive material of one or more of the number of HVIso devices.

16. The microelectronic device of claim 12, wherein a distance between a dummy device of the number of dummy devices and an adjacent dummy device of the dummy devices is different than a distance between an HVIso device of the number of HVIso devices and an adjacent HVIso device of the number of HVIso devices.

17. The microelectronic device of claim 12, wherein the conductive material of each of the number of HVIso devices has an at least substantially consistent width across the series of HVIso devices.

18. An electronic system comprising:
an input device;
an output device;
a processor device operably coupled to the input device and the output device; and
a memory device operably coupled to the processor device and comprising:
a source structure;
a high voltage isolation (HVIso) block defining a first edge and a second edge opposite the first edge, the HVIso block comprising:
a number of HVIso devices in a series in a first direction, each HVIso device of the number of HVIso devices comprising:
a source node in electrical contact with the source structure;
a drain node;
a MUX gate configured to electrically disconnect the source node from the drain node;
a low voltage node;
an isolation gate configured to electrically disconnect the source node from the low voltage node;
a conductive material extending across a length of the HVIso block and operably connected to the source node, the drain node, the MUX gate, the isolation gate, and the low voltage node;
a number of dummy devices in the series of the number of HVIso devices and located closer to the first edge or the second edge than the number of HVIso devices, the number of dummy devices where a distance between at least two dummy devices in the series is different than a distance between each of the number of HVIso devices; and
an insulative material located between HVIso devices of the number of first HVIso devices and between dummy devices of the number of dummy devices in the series.

19. The electronic system of claim 18, wherein each dummy device of the number of dummy devices comprises a conductive material extending across the length of the HVIso block, wherein the conductive material of at least one of the number of dummy devices has a width different than each of the number of HVIso devices.

20. The electronic system of claim 18, further comprising circuitry electrically connected with the number of HVIso devices but electrically disconnected from the number of dummy devices.
